(19) United States
(12) Patent Application Publication
(10) Pub. No.: US 2026/0073953 A1
(43) Pub. Date: Mar. 12, 2026

(54) SEMICONDUCTOR MEMORY DEVICE

(71) Applicant: Kioxia Corporation, Tokyo (JP)

(72) Inventors: Saho OHSAWA, Yokkaichi (JP); Yosuke MURAKAMI, Mie (JP); Naoya YOSHITAKA, Yokkaichi (JP)

(73) Assignee: Kioxia Corporation, Tokyo (JP)

(21) Appl. No.: 19/065,423

(22) Filed: Feb. 27, 2025

(30) Foreign Application Priority Data
Sep. 9, 2024 (JP) 2024-154835

(51) Int. Cl. G11C 5/06; G11C 16/04; H10B 43/10; H10B 43/35

(52) U.S. Cl. CPC G11C 5/063; G11C 16/0483; H10B 43/10; H10B 43/35

(57) ABSTRACT

In general, according to one embodiment, a semiconductor memory device includes: stacked layers including a plurality of interconnect layers and first insulating films alternately stacked in a first direction; a memory pillar extending and passing through the stacked layers in the first direction, wherein the memory pillar includes a semiconductor, a second insulating film provided between the semiconductor and the stacked layers, a charge storage film provided between the second insulating film and the stacked layers, a plurality of third insulating films provided between the charge storage film and the interconnect layers, and a plurality of fourth insulating films provided between the charge storage film and the first insulating films; and a fifth insulating film having a lower etching rate to hydrofluoric acid than the fourth insulating films, provided to cover side surface of the interconnect layers.

### CROSS-REFERENCE TO RELATED APPLICATION

This application is based upon and claims the benefit of priority from prior Japanese Patent Application No. 2024-154835, filed September 9, 2024, the entire contents of which are incorporated herein by reference.

### FIELD

Embodiments described herein relate generally to a semiconductor memory device.

### BACKGROUND

A NAND flash memory is known as a semiconductor memory device capable of storing data in a nonvolatile manner. In the NAND flash memory, there is a case where a three-dimensional memory configuration is adopted for higher integration density and greater capacity.

### BRIEF DESCRIPTION OF THE DRAWINGS

FIG. 1 is a block diagram illustrating an example of a configuration of a memory system according to an embodiment.

FIG. 2 is a circuit diagram illustrating an example of a circuit configuration of a memory cell array included in a semiconductor memory device according to the embodiment.

FIG. 3 is a plan view illustrating an example of a planar layout of the memory cell array included in the semiconductor memory device according to the embodiment.

FIG. 4 is a plan view illustrating an example of a planar layout in a memory area of the memory cell array included in the semiconductor memory device according to the embodiment.

FIG. 5 is a cross-sectional view taken along line V-V in FIG. 4, FIG. 5 illustrating an example of a cross-sectional configuration in the memory area of the memory cell array included in the semiconductor memory device according to the embodiment.

FIG. 6 is an enlarged cross-sectional view of an area VI in FIG. 5, FIG. 6 illustrating an example of a cross-sectional configuration in the memory area of the memory cell array included in the semiconductor memory device according to the embodiment.

FIG. 7 is a cross-sectional view taken along line VII-VII in FIG. 5, FIG. 7 illustrating an example of a cross-sectional configuration of a memory pillar included in the semiconductor memory device according to the embodiment.

FIG. 8 is a cross-sectional view taken along line VIII-VIII in FIG. 5, FIG. 8 illustrating an example of a cross-sectional configuration of the memory pillar included in the semiconductor memory device according to the embodiment.

FIG. 9 is a plan view illustrating an example of a planar layout in a hookup area of the memory cell array included in the semiconductor memory device according to the embodiment.

FIG. 10 is a cross-sectional view taken along line X'-X' in FIG. 9, in the hookup area of the memory cell array included in the semiconductor memory device according to the embodiment.

FIG. 11 is a flowchart illustrating an example of manufacturing steps of the memory cell array included in the semiconductor memory device according to the embodiment.

FIG. 12 is a cross-sectional view illustrating an example of a cross-sectional configuration during the manufacture of the memory cell array included in the semiconductor memory device according to the embodiment.

FIG. 13 is a cross-sectional view illustrating an example of a cross-sectional configuration during the manufacture of the memory cell array included in the semiconductor memory device according to the embodiment.

FIG. 14 is a cross-sectional view illustrating an example of a cross-sectional configuration during the manufacture of the memory cell array included in the semiconductor memory device according to the embodiment.

FIG. 15 is a cross-sectional view illustrating an example of a cross-sectional configuration during the manufacture of the memory cell array included in the semiconductor memory device according to the embodiment.

FIG. 16 is a cross-sectional view illustrating an example of a cross-sectional configuration during the manufacture of the memory cell array included in the semiconductor memory device according to the embodiment.

FIG. 17 is a cross-sectional view illustrating an example of a cross-sectional configuration during the manufacture of the memory cell array included in the semiconductor memory device according to the embodiment.

FIG. 18 is a cross-sectional view illustrating an example of a cross-sectional configuration during the manufacture of the memory cell array included in the semiconductor memory device according to the embodiment.

FIG. 19 is a cross-sectional view illustrating an example of a cross-sectional configuration during the manufacture of the memory cell array included in the semiconductor memory device according to the embodiment.

FIG. 20 is a cross-sectional view illustrating an example of a cross-sectional configuration during the manufacture of the memory cell array included in the semiconductor memory device according to the embodiment.

FIG. 21 is a cross-sectional view illustrating an example of a cross-sectional configuration during the manufacture of the memory cell array included in the semiconductor memory device according to the embodiment.

FIG. 22 is a cross-sectional view illustrating an example of a cross-sectional configuration during the manufacture of the memory cell array included in the semiconductor memory device according to the embodiment.

FIG. 23 is a cross-sectional view illustrating an example of a cross-sectional configuration during the manufacture of the memory cell array included in the semiconductor memory device according to the embodiment.

FIG. 24 is a cross-sectional view illustrating an example of a cross-sectional configuration during the manufacture of the memory cell array included in the semiconductor memory device according to the embodiment.

FIG. 25 is a cross-sectional view illustrating an example of a cross-sectional configuration in a memory area of a memory cell array included in a semiconductor memory device according to a first modification of the embodiment.

FIG. 26 is a cross-sectional view illustrating an example of a cross-sectional configuration in a memory area of a memory cell array included in a semiconductor memory device according to a second modification of the embodiment.

### DETAILED DESCRIPTION

In general, according to one embodiment, a semiconductor memory device includes: a plurality of interconnect layers and a plurality of first insulating films provided to extend over a first area and a second area that are arranged, as viewed in a first direction, in a second direction crossing the first direction, and alternately stacked in the first direction; a memory pillar extending and passing through the interconnect layers and the first insulating films in the first direction in the second area, and in which portions passing through the interconnect layers function as memory cells, wherein the memory pillar includes a semiconductor extending in the first direction, a second insulating film provided between the semiconductor, and the interconnect layers and the first insulating films, a charge storage film provided between the second insulating film, and the interconnect layers and the first insulating films, a plurality of third insulating films provided between the charge storage film and the interconnect layers, and a plurality of fourth insulating films including a first film type and provided between the charge storage film and the first insulating films; and a fifth insulating film, including a second film type having a lower etching rate to hydrofluoric acid than the first film type, provided in the first area in such a manner as to cover side surface portions in the second direction at end portions of the interconnect layers.

Hereinafter, embodiments are described with reference to the accompanying drawings. The drawings are schematic ones, and the dimensions and ratios in the drawings are not necessarily identical to real ones. In the description below, structural elements having substantially identical functions and structures are denoted by an identical reference sign. In a case where elements having similar structures are particularly distinguished, there is a case in which mutually different characters or numerals are added to the end of an identical reference sign.

In the description below, an expression that a certain first element is "coupled" to another second element includes a mode in which the first element is indirectly coupled to the second element via an intermediate element that is always or selectively rendered conductive, or is directly coupled to the second element without via the intermediate element.

### 1. CONFIGURATION

### 1.1. Memory System

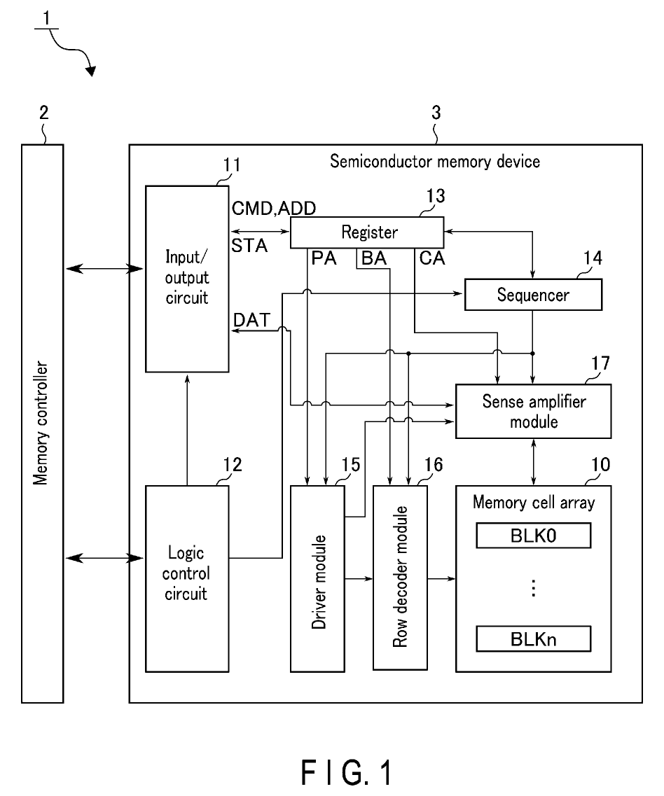

A semiconductor memory device according to an embodiment is described. FIG. 1 is a block diagram illustrating an example of a configuration of a memory system according to the embodiment. A memory system 1 is a memory device configured to be coupled to an external host device (not illustrated). The memory system 1 is, for example, a memory card such as an SD^{TM} card, a UFS (Universal Flash Storage), or an SSD (Solid State Drive). The memory system 1 includes a memory controller 2 and a semiconductor memory device 3.

The memory controller 2 is composed of, for example, an integrated circuit such as an SoC (System on a Chip). The memory controller 2 controls the semiconductor memory device 3, based on a request from an external host device. Specifically, the memory controller 2 writes data, write of which is requested from the external host device, into the semiconductor memory device 3. In addition, the memory controller 2 reads out data, read of which is requested from the external host device, from the semiconductor storage device 3, and outputs the read-out data to the external host device.

The semiconductor memory device 3 is, for example, a NAND flash memory capable of storing data in a nonvolatile manner.

The communication between the memory controller 2 and the semiconductor memory device 3 supports, for example, an SDR (Single Data Rate) interface, a toggle DDR (Double Data Rate) interface, or an ONFI (Open NAND Flash Interface).

### 1.2. Semiconductor Memory Device

Next, referring to the block diagram of FIG. 1, an internal configuration of the semiconductor memory device 3 according to the embodiment is described. The semiconductor memory device 3 includes, for example, a memory cell array 10, an input/output circuit 11, a logic control circuit 12, a register 13, a sequencer 14, a driver module 15, a row decoder module 16, and a sense amplifier module 17.

The memory cell array 10 is a set including a group of memory cell transistors, and structural elements coupled to the memory cell transistors. The memory cell array 10 includes a plurality of blocks BLK0 to BLKn (n is an integer of 1 or more). The block BLK is a set of memory cell transistors capable of memorizing data in a nonvolatile manner. The block BLK is used as, for example, an erase unit at a time of erasing data stored in the memory cell transistors. In addition, a plurality of bit lines and a plurality of word lines are provided in the memory cell array 10. Each memory cell transistor is associated with, for example, a combination of one bit line and one word line. A detailed configuration of the memory cell array 10 will be described later.

The input/output circuit 11 is an interface circuit that controls transmission/reception of input/output signals to/from the memory controller 2. The input/output signals include, for example, data DAT, a command CMD, address information ADD, and status information STA. The input/output circuit 11 inputs and outputs the data DAT between the sense amplifier module 17 and the memory controller 2. The input/output circuit 11 outputs the command CMD and address information ADD, which are transferred from the memory controller 2, to the register 13. The input/output circuit 11 outputs the status information STA, which is transferred from the register 13, to the memory controller 2.

The logic control circuit 12 receives a control signal that is input from the memory controller 2. Based on the control signal, the logic control circuit 12 controls the input/output circuit 11 and the sequencer 14. For example, the logic control circuit 12 notifies the input/output circuit 11 that the input/output signal received by the input/output circuit 11 is the command CMD, address information ADD, or the like. The logic control circuit 12 orders the input/output circuit 11 to output the input/output signal. The logic control circuit 12 controls the sequencer 14, and enables the semiconductor memory device 3. In addition, the logic control circuit 12 outputs to the memory controller 2 a signal indicating whether the semiconductor memory device 3 is in a ready state (a state in which it can accept commands from the outside)or a busy state (a state in which it cannot accept commands from the outside).

The register 13 temporarily stores the command CMD, address information ADD and status information STA. The command CMD includes, for example, instructions for causing the sequencer 14 to execute a read operation, a write operation, and an erase operation. The address information ADD includes, for example, a block address BA, a page address PA, and a column address CA. For example, the block address BA, page address PA, and column address CA are used for selecting a block BLK, a word line and a bit line, respectively. The status information STA is used in order to notify the memory controller 2 whether an operation is normally completed. The status information STA is updated based on the control of the sequencer 14, and is transferred to the input/output circuit 11.

The sequencer 14 controls an overall operation of the semiconductor memory device 3. For example, based on the command CMD stored in the register 13, the sequencer 14 controls the driver module 15, row decoder module 16 and sense amplifier module 17, and executes the read operation, write operation and erase operation.

The driver module 15 generates voltages of different magnitudes, which are used in the read operation, write operation and erase operation. The driver module 15 supplies the generated voltages to the row decoder module 16 and sense amplifier module 17. In addition, the driver module 15 applies the generated voltage, for example, to a signal line corresponding to a word line that is selected based on the page address PA stored in the register 13.

The row decoder module 16 selects, for example, based on the block address BA stored in the register 13, one corresponding block BLK in the memory cell array 10. The row decoder module 16 transfers, for example, a voltage of a signal line, which is applied by the driver module 15, to a selected word line in a selected block BLK.

The sense amplifier module 17 includes a sense amplifier capable of determining data, based on the voltage of an associated bit line, and a latch circuit that temporarily stores data. In the write operation, the sense amplifier module 17 applies a desired voltage to each bit line, in accordance with write data DAT received from the input/output circuit 11. In addition, in the read operation, the sense amplifier module 17 determines data stored in the memory cell transistor, based on the magnitude of the voltage of the bit line. Thereafter, the sense amplifier module 17 transfers the result of the determination to the input/output circuit 11 as read data DAT.

The semiconductor memory device 3 according to the embodiment includes, for example, a structure that is formed such that a first semiconductor substrate on which various control circuits are formed, and a second semiconductor substrate on which the memory cell array 10 is formed, are bonded to each other. Each of the first and second semiconductor substrates is, for example, a silicon substrate. The various control circuits formed on the first semiconductor substrate includes, for example, the input/output circuit 11, logic control circuit 12, register 13, sequencer 14, driver module 15, row decoder module 16 and sense amplifier module 17. In the description below, an example is described in which in the manufacturing step of the semiconductor memory device 3, the second semiconductor substrate is removed after the first and second semiconductor substrates are bonded. Note that, depending on the configuration of the memory cell array 10, a part of the second semiconductor may be left after the bonding.

### 1.3. Circuit Configuration of Memory Cell Array

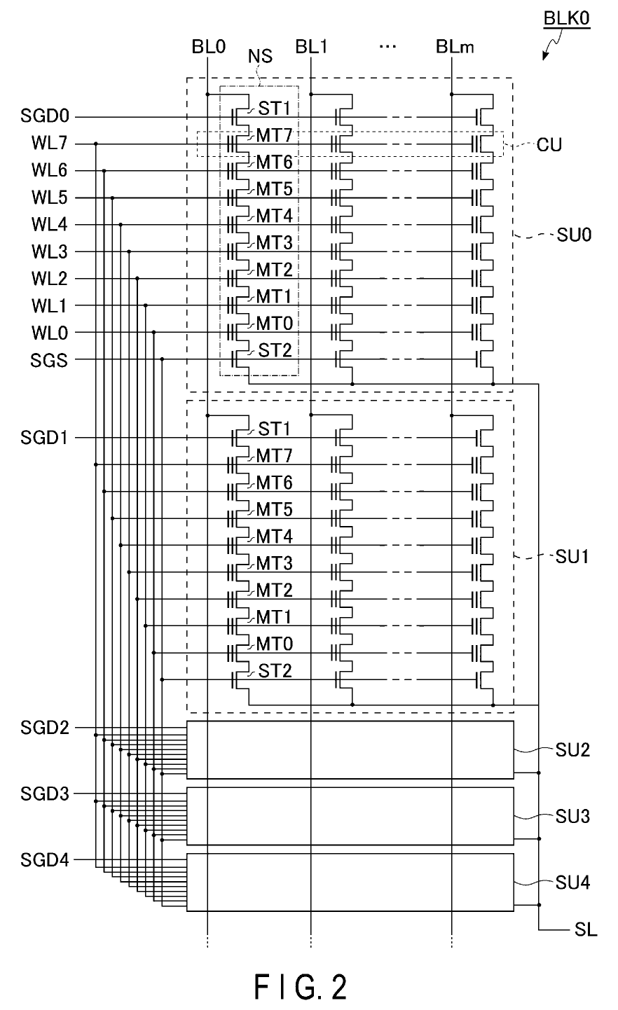

FIG. 2 is a circuit diagram illustrating an example of the circuit configuration of the memory cell array included in the semiconductor memory device according to the embodiment. FIG. 2 illustrates the block BLK0. The block BLK0 includes, for example, five string units SU0 to SU4.

Each string unit SU includes a plurality of NAND strings NS that are associated with bit lines BL0 to BLm (m is an integer of 1 or more), respectively. Each NAND string NS includes, for example, eight memory cell transistors MT0 to MT7 and select transistors ST1 and ST2. Each memory cell transistor MT includes a control gate and a charge storage film, and memorizes data in a nonvolatile manner, based on the quantity of charge in the charge storage film. Each of the select transistors ST1 and ST2 is used to select the string unit SU at times of various operations.

In each NAND string NS, the memory cell transistors MT0 to MT7 are coupled in series in the named order. The drain of the select transistor ST1 is coupled to the associated bit line BL, and the source of the select transistor ST1 is coupled to the drain of the memory cell transistor MT7. The drain of the select transistor ST2 is coupled to the source of the memory cell transistor MT0, and the source of the select transistor ST2 is coupled to a source line SL.

The control gates of the memory cell transistors MT0 to MT7 in the same block BLK are coupled to the word lines WL0 to WL7, respectively. The gates of the select transistors ST1 in the string units SU0 to SU4 are coupled to select gate lines SGD0 to SGD4, respectively. The gates of the select transistors ST2 in the same block BLK are coupled to the select gate line SGS.

Different column addresses CA are allocated to the bit lines BL0 to BLm. Each bit line BL is shared by the NAND strings NS to which an identical column address CA is allocated between a plurality of blocks BLK. Each of the word lines WL0 to WL7 is provided for each block BLK. The source line SL is shared by, for example, a plurality of blocks BLK.

A set of memory cell transistors MT, which are coupled to a common word line WL in one string unit SU, is referred to as, for example, "cell unit CU". For example, a storage capacity of the cell unit CU including memory cell transistors MT each storing 1-bit data is defined as "one page data". Each cell unit CU can have a storage capacity of two page data or more, in accordance with the number of bits of data that the memory cell transistor MT memorizes.

Note that the circuit configuration of the memory cell array 10 included in the semiconductor memory device 3 according to the embodiment is not limited to the circuit configuration described above. For example, the number of string units SU included in each block BLK can be designed to be a freely selected number. The number of memory cell transistors MT included in each NAND string NS, and the number of select transistors ST1 and ST2 included in each NAND string NS, can be designed to be freely selected numbers.

### 1.4. Configuration of Memory Cell Array

Hereinafter, an example of the configuration of the memory cell array 10 included in the semiconductor memory device 3 according to the embodiment is described. In the description below, an extending direction of the word line WL is defined as an X direction. An extending direction of the bit line BL is defined as a Y direction. A direction in which stacked interconnects corresponding to the select gate lines SGD and SGS and word lines WL are stacked, as viewed from the source line SL side, is defined as a Z direction or an upward direction. A direction opposite to the upward direction is defined as a downward direction. In plan views, in order to enhance the visibility of drawings, hatching is added as appropriate. The hatching added in the plan views is not necessarily related to the materials or characteristics of structural elements to which the hatching is added.

### 1.4.1. Outline

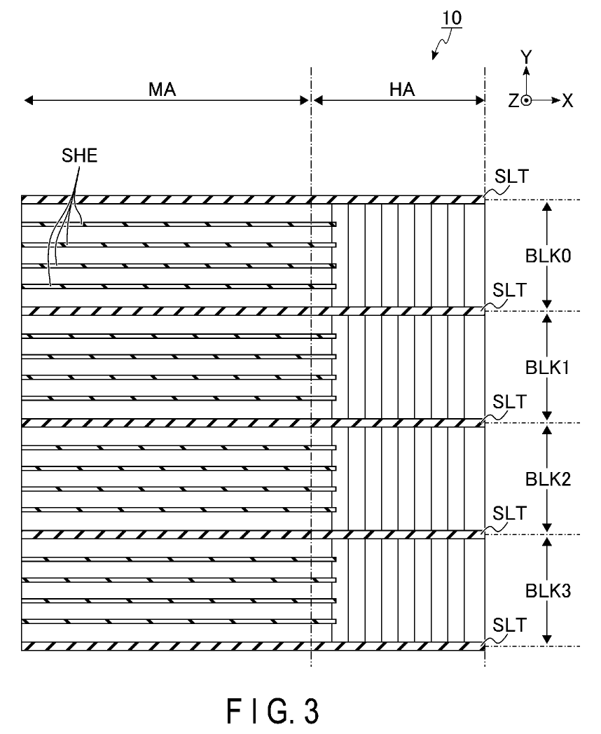

FIG. 3 is a plan view illustrating an example of a planar layout of the memory cell array included in the semiconductor memory device according to the embodiment. FIG. 3 illustrates areas corresponding to four blocks BLK0 to BLK3. Serial numbers at the end of "BLK" in order to distinguish blocks BLK are added in an ascending order, as viewed from the upper side on the drawing sheet. In the memory cell array 10, for example, the layout illustrated in FIG. 3 is repeatedly arranged in the Y direction. As illustrated in FIG. 3, the memory cell array 10 includes a plurality of members SLT and a plurality of members SHE. The planar layout of the memory cell array 10 is divided into a memory area MA and a hookup area HA, for example, in the X direction.

The memory area MA is an area that includes a plurality of NAND strings NS and is used for memorizing data. The hookup area HA is an area used for coupling the stacked interconnects, which are formed such that a plurality of interconnect layers (for example, word lines WL0 to WL7, and select gate lines SGS and SGD) are stacked by being spaced apart in the Z direction, and the row decoder module 16.

The members SLT extend in the X direction and are arranged in the Y direction. Each member SLT extends across the memory area MA and the hookup area HA in the X direction in a boundary area between mutually neighboring blocks BLK. In other words, each of the areas divided by the members SLT corresponds to one block BLK in the memory cell array 10. Each member SLT is configured, for example, such that an insulator and a plate-shaped contact are buried. Each member SLT divides stacked interconnects that neighbor each other via this member SLT.

The members SHE are arranged in the memory area MA. The members SHE are provided to extend across the memory area MA in the X direction, and are arranged in the Y direction. An end portion of each member SHE, on the right side on the drawing sheet, is included in the hookup area HA. For example, in the memory area MA, four members SHE are disposed between members SLT that neighbor each other in the Y direction. Each of the areas of the memory area MA, which are divided by the members SLT and SHE, corresponds to one string unit SU in the memory cell array 10. Each member SHE is configured, for example, such that an insulator is buried. Each member SHE divides select gate lines SGD that neighbor each other via the member SHE.

Note that the planar layout of the memory cell array 10 included in the semiconductor memory device 3 according to the embodiment is not limited to the layout described above. For example, the number of members SHE arranged between the mutually neighboring members SLT can be designed to be a freely selected number. The number of string units SU formed between the mutually neighboring members SLT can be changed based on the number of members SHE arranged between the mutually neighboring members SLT.

### 1.4.2. Memory Area

### Planar Layout

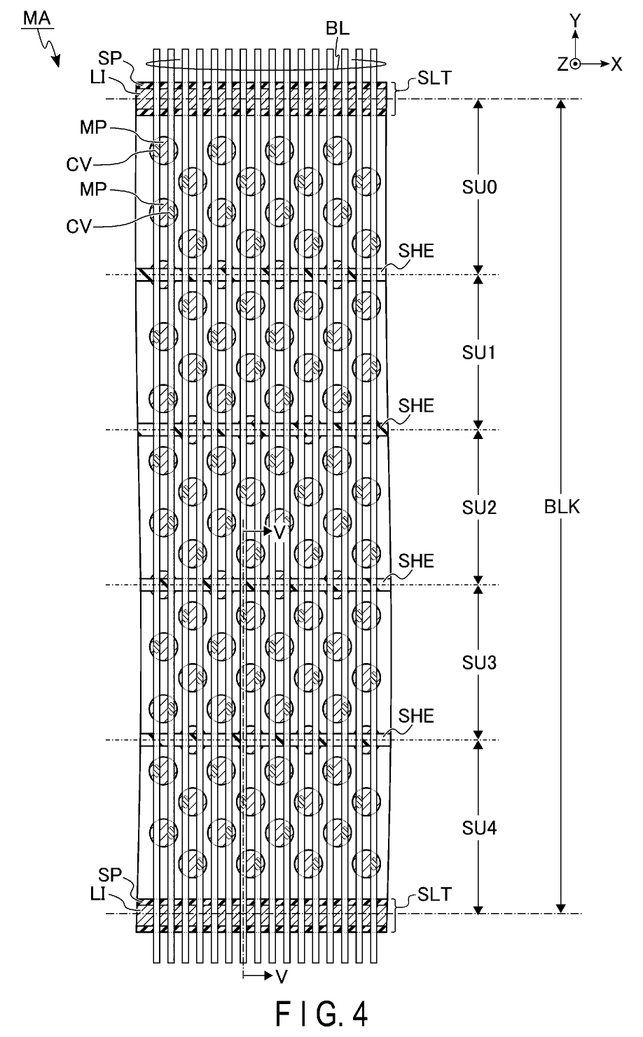

FIG. 4 is a plan view illustrating an example of a planar layout in the memory area of the memory cell array included in the semiconductor memory device according to the embodiment. As illustrated in FIG. 4, in the memory area MA, the memory cell array 10 includes a plurality of memory pillars MP, a plurality of contacts CV, and a plurality of bit lines BL. In addition, each member SLT includes a contact LI and a spacer SP.

Each of the memory pillars MP functions, for example, as one NAND string NS. The memory pillars MP are arranged, for example, in a staggered fashion in 24 rows in the Y direction in the area between two mutually neighboring members SLT. In the example illustrated in FIG. 4, one member SHE overlaps each of the memory pillars MP of the fifth row, tenth row, 15th row and 20th row as counted from the upper side on the drawing sheet.

The bit lines BL extend in the Y direction and are arranged in the X direction. Each bit line BL is disposed to overlap at least one memory pillar MP in each string unit SU. In the example illustrated in FIG. 4, two bit lines BL are arranged in such a manner as to overlap one memory pillar MP. In a case where a plurality of bit lines BL overlap a memory pillar MP, one of the bit lines BL and a corresponding memory pillar MP are electrically coupled via the contact CV. Note that in a case where only one bit line BL overlaps a memory pillar MP, this bit line BL and a corresponding memory pillar MP are electrically coupled via the contact CV.

For example, the contact CV between the memory pillar MP, which is overlapped by the member SHE, and the bit line BL is omitted. In other words, the contact CV between the memory pillar MP, which is in contact with two different select gate lines SGD, and the bit line BL is omitted. The numbers and arrangements of the memory pillars MP and members SHE between the neighboring members SLT are not limited to those in the configuration illustrated in FIG. 4, and can be changed as appropriate. For example, the number of bit lines BL overlapping each memory pillar MP can be designed to be a freely selected number.

The contact LI is a conductor that extends in an XZ plane. A lower surface of the contact LI is in contact with a source line SL (not illustrated). The spacer SP is an insulator provided on a side surface of the contact LI. In other words, the spacer SP is provided in contact with the contact LI in such a manner as to sandwich the contact LI in the Y direction.

### Cross-Sectional Configuration

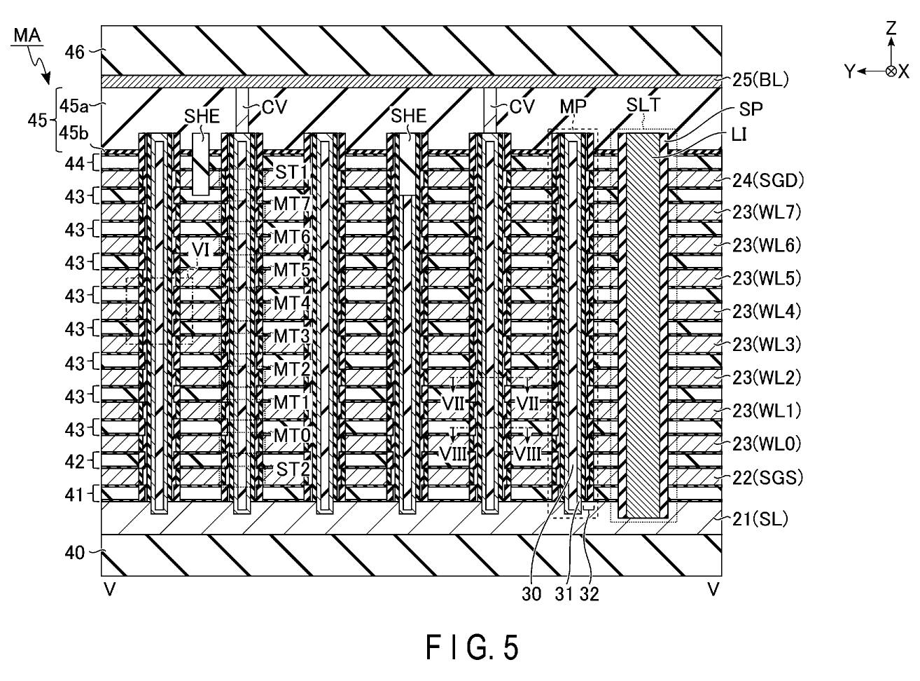

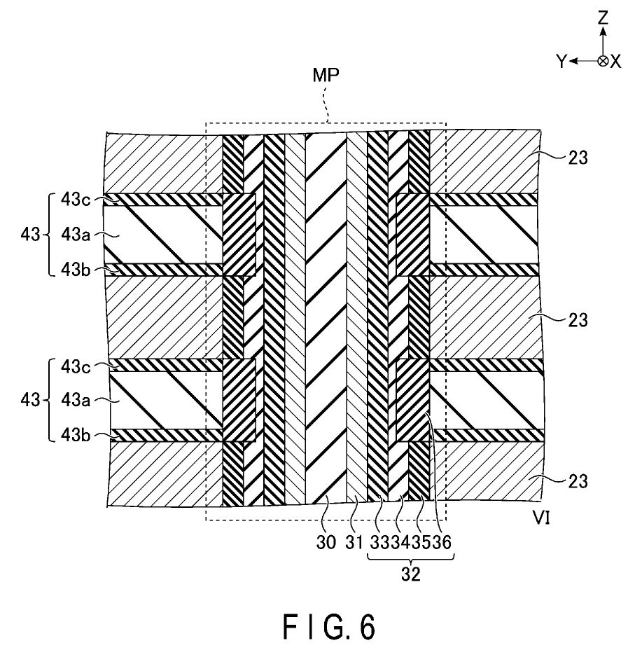

FIG. 5 is a cross-sectional view taken along line V-V in FIG. 4, FIG. 5 illustrating an example of a cross-sectional configuration in the memory area of the memory cell array included in the semiconductor memory device according to the embodiment. As illustrated in FIG. 5, the memory cell array 10 further includes interconnect layers 21 to 25 and insulator layers 40 to 46. In addition, FIG. 6 is an enlarged cross-sectional view of an area VI in FIG. 5, FIG. 6 illustrating an example of a cross-sectional configuration in the memory pillar included in the semiconductor memory device according to the embodiment.

As illustrated in FIG. 5, the insulator layer 40, interconnect layer 21, insulator layer 41, interconnect layer 22, and insulator layer 42 are stacked in the named order. The interconnect layer 21 is formed, for example, in a plate shape extending in the X direction on an XY plane. The interconnect layer 21 is used as the source line SL. The interconnect layer 21 includes, for example, silicon doped with phosphorus. The interconnect layer 22 is formed, for example, in a plate shape extending in the X direction on the XY plane. The interconnect layer 22 is used as the select gate line SGS. The interconnect layer 22 includes, for example, tungsten (W). Note that the interconnect layer 22 may include, for example, a barrier film including aluminum oxide (AlO), in such a manner as to cover a surface of the interconnect layer 22. The insulator layer 40 includes, for example, an interconnect and a pad, which are not illustrated, for the coupling between the semiconductor memory device 3 and an external device.

The interconnect layers 23 and the insulator layers 43 are alternately stacked one by one above the insulator layer 42. In the example illustrated in FIG. 5, eight interconnect layers 23 and eight insulator layers 43 are alternately stacked one by one. Each interconnect layer 23 is formed, for example, in a plate shape extending in the X direction on the XY plane. The interconnect layers 23 are used as the word lines WL0 to WL7 in order from the interconnect layer 22 side. Each interconnect layer 23 includes, for example, tungsten. Note that each interconnect layer 23 may include, for example, a barrier film including AlO, in such a manner as to cover a surface of the interconnect layer 23.

An interconnect layer 24, an insulator layer 44 and an insulator layer 45 are stacked in the named order above the uppermost insulator layer 43. The interconnect layer 24 is formed, for example, in a plate shape extending in the X direction on the XY plane. The interconnect layer 24 is used as the select gate line SGD. The interconnect layer 24 includes, for example, tungsten. Note that the interconnect layer 24 may include, for example, a barrier film including AlO, in such a manner as to cover a surface of the interconnect layer 24.

Note that the number of layers of the interconnect layers 22, 23 and 24 are not limited to the above-described configuration. For example, a plurality of interconnect layers 22 or a plurality of interconnect layers 24 may be provided. For example, nine or more interconnect layers 23 may be stacked. The number of layers of the insulator layers 42, 43 and 44 may vary in accordance with the number of layers of the interconnect layers 22, 23 and 24.

An interconnect layer 25 is stacked above the insulator layer 45. The interconnect layer 25 is formed, for example, in a line shape extending in the Y direction. The interconnect layer 25 is used as the bit line BL. In an area not illustrated, a plurality of interconnect layers 25 are arranged in the X direction. The interconnect layer 25 includes, for example, copper.

An insulator layer 46 is stacked above the interconnect layer 25. The insulator layer 46 includes a plurality of interconnects (not illustrated), for example, for the memory cell array 10 to be coupled to the row decoder module 16 and sense amplifier module 17 that are provided further upward.

As illustrated in FIG. 6, each insulator layer 43 includes a first insulating film 43a, a second insulating film 43b and a third insulating film 43c. The first insulating film 43a is provided in a central portion of the insulator layer 43. The first insulating film 43a includes, for example, silicon oxide (SiO). The second insulating film 43b is provided in such a manner as to cover a lower surface of the corresponding first insulating film 43a. The third insulating film 43c is provided in such a manner as to cover an upper surface of the corresponding first insulating film 43a. Specifically, the second insulating film 43b and third insulating film 43c are provided in such a manner as to sandwich the corresponding first insulating film 43a in the Z direction. The second insulating film 43b and third insulating film 43c include different film types from the first insulating film 43a, and include, for example, silicon oxycarbide (SiOC). In a case where SiOC is used for the second insulating film 43b and third insulating film 43c, the element ratio of carbon is adjusted such that the etching rate at a time of etching using hydrofluoric acid becomes lower than in the film type used for a cover insulating film 36 to be described later.

Although not illustrated, each of the insulator layers 41, 42 and 44 similarly includes a first insulating film, a second insulating film and a third insulating film. Each insulating film is provided in a central portion of the corresponding insulator layer 41, 42 or 44. Each first insulating film includes, for example, SiO. Each second insulating film is provided in such a manner as to cover the lower surface of the first insulating film. Each third insulating film is provided in such a manner as to cover the upper surface of the corresponding first insulating film. Specifically, the second insulating film and the third insulating film are provided in such a manner as to sandwich the corresponding first insulating film in the Z direction. Each second insulating film and each third insulating film includes a different film type from the first insulating film, and includes, for example, SiOC. In a case of using SiOC for the second insulating film and third insulating film, the element ratio of carbon is adjusted such that the etching rate at a time of etching using hydrofluoric acid becomes lower than in the film type used for the cover insulating film 36 to be described later.

As illustrated in FIG. 5, the insulator layer 45 includes an insulator 45a and a coat film 45b. The insulator 45a includes, for example, TEOS (Tetra Ethoxy Silane). The coat film 45b is provided between the insulator 45a and the underlying stacked interconnect. The coat film 45b has, for example, a less thickness in the Z direction than each of the interconnect layers 22 to 24 and insulator layers 41 to 44, and has a film thickness of about 6 nm. The coat film 45b includes a different film type from the insulator 45a, and includes, for example, SiOC. In a case of using SiOC for the coat film 45b, the element ratio of carbon is adjusted such that the etching rate is adjusted such that the etching rate at a time of etching using hydrofluoric acid becomes lower than in the film type used for the cover insulating film 36 to be described later.

Each of the memory pillars MP extends in the Z direction. Each memory pillar MP penetrates the interconnect layers 22 to 24 and insulator layers 41 to 44.

Each memory pillar MP includes, for example, a core film 30, a semiconductor film 31 and a stacked film 32. The core film 30 extends in the Z direction. For example, an upper end of the core film 30 is located in the insulator layer 45, and a lower end of the core film 30 is located in the interconnect layer 21. The core film 30 includes, for example, an insulator such as SiO. The semiconductor film 31 covers, for example, a periphery of the core film 30. At the lower end of the memory pillar MP, a part of the semiconductor film 31 is in contact with the interconnect layer 21. The semiconductor film 31 is used as channels (current paths) of the memory cell transistors MT0 to MT7 and select transistors ST1 and ST2. The semiconductor film 31 includes, for example, silicon. The stacked film 32 covers a side surface of the semiconductor film 31, except for a part where the semiconductor film 31 and the interconnect layer 21 are in contact with each other.

In the structure of the memory pillar MP illustrated in FIG. 5, a part at which the memory pillar MP and the interconnect layer 22 intersect functions as the select transistor ST2. Parts at which the memory pillar MP and the interconnect layers 23 intersect function as the memory cell transistors MT0 to MT7. A part at which the memory pillar MP and the interconnect layer 24 intersect functions as the select transistor ST1.

As illustrated in FIG. 6, the stacked film 32 includes, for example, a tunnel insulating film 33, a charge storage film 34, a block insulating film 35, and a cover insulating film 36. The tunnel insulating film 33 is used as a potential barrier between the semiconductor film 31 and the charge storage film 34. The tunnel insulating film 33 includes, for example, SiO. The charge storage film 34 has a function of storing charge. The charge storage film 34 includes, for example, silicon nitride (SiN). The block insulating film 35 suppresses back-tunneling of charge from the interconnect layer 23 to the memory pillar MP. The block insulating film 35 includes, for example, SiO. The cover insulating film 36 divides the charge storage film 34 in a pseudo-manner. The cover insulating film 36 suppresses movement in the Z direction of the charge stored in the charge storage film 34. Thereby, an interference of data between the memory cell transistors MT can be suppressed. The cover insulating film 36 includes a different film type from the coat film 45b, and includes, for example, SiO, hafnium oxide (HfO), or zirconium oxide (ZrO).

A columnar contact CV is provided on an upper surface of the semiconductor film 31 in the memory pillar MP. In the area illustrated in FIG. 5, two contacts CV corresponding two memory pillars MP among six memory pillars MP are illustrated. The memory pillars MP, which do not overlap the members SHE and are not coupled to the contacts CV in this area, are coupled to other contacts CV in an area not illustrated.

One interconnect layer 25, i.e., one bit line BL, is in contact with an upper surface of each contact CV. One contact CV is coupled to one interconnect layer 25 in each of the spaces divided by the members SLT and SHE. Specifically, each of the interconnect layers 25 is electrically coupled to, for example, one memory pillar MP in each area between mutually neighboring members SLT and SHE, and one memory pillar MP in each area between two mutually neighboring members SHE.

The members SLT are formed in such a manner as to extend along the XZ plane. Each of the members SLT divides the interconnect layers 22 to 24 and insulator layers 41 to 44 in the Y direction. Each member SLT may have, for example, a taper shape having a width in the Y direction decreasing from above to below.

In the member SLT, the contact LI is provided in such a manner as to extend along the XZ plane, and the spacer SP is provided between the contact LI and the interconnect layers 22 to 24 and insulator layers 41 to 45. An upper end of the contact LI is located, for example, in the insulator layer 45. A lower end of the contact LI is located, for example, in the interconnect layer 21. Note that the contact LI may be omitted, depending on the configuration of the memory cell array 10.

The member SHE is formed in a plate shape extending along the XZ plane, and divides the interconnect layer 24. An upper end of the member SHE is located in the insulator layer 45. A lower end of the member SHE is located, for example, in the uppermost insulator layer 43. The member SHE includes, for example, an insulator such as SiO. Note that the upper end of the member SHE and the upper end of the member SLT may be flush with each other, or may not be flush with each other. In addition, the upper end of the member SHE and the upper end of the memory pillar MP may be flush with each other, or may not be flush with each other.

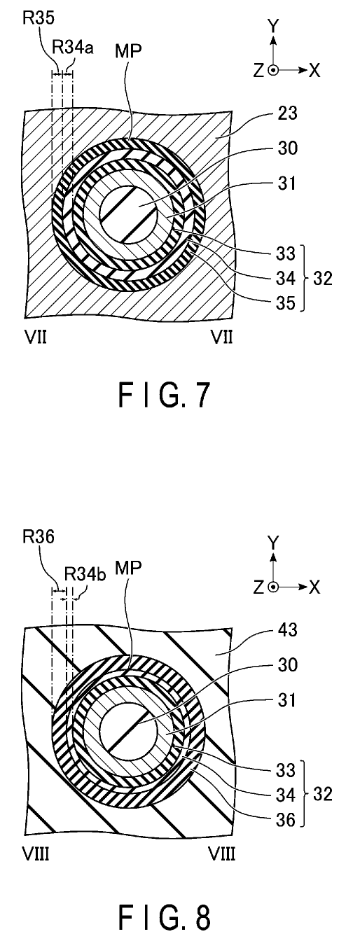

FIG. 7 is a cross-sectional view along line VII-VII in FIG. 5, FIG. 7 illustrating an example of a cross-sectional configuration of the memory pillar MP included in the semiconductor memory device according to the embodiment. To be more specific, FIG. 7 illustrates a cross-sectional configuration of the memory pillar MP in the XY plane including one of the interconnect layers 23. FIG. 8 is a cross-sectional view along line VIII-VIII in FIG. 5, FIG. 8 illustrating an example of a cross-sectional configuration of the memory pillar MP included in the semiconductor memory device according to the embodiment. To be more specific, FIG. 8 illustrates a cross-sectional configuration of the memory pillar MP in the XY plane including one of the insulator layers 43.

As illustrated in FIG. 7, in the cross section including the interconnect layer 23, the memory pillar MP has a circular cross-sectional shape. As illustrated in FIG. 6 and FIG. 7, in the cross section including the interconnect layer 23, the core film 30 is provided, for example, in a central portion of the memory pillar MP. The semiconductor film 31 surrounds a side surface of the core film 30. The tunnel insulating film 33 surrounds a side surface of the semiconductor film 31. The charge storage film 34 surrounds a side surface of the tunnel insulating film 33. The block insulating film 35 surrounds a side surface of the charge storage film 34. The interconnect layer 23 surrounds a side surface of the block insulating film 35.

As illustrated in FIG. 8, in the cross section including the insulator layer 43, the memory pillar MP has a circular cross-sectional shape. As illustrated in FIG. 6 and FIG. 8, in the cross section including the insulator layer 43, the core film 30 is provided, for example, in a central portion of the memory pillar MP. The semiconductor film 31 surrounds a side surface of the core film 30. The tunnel insulating film 33 surrounds a side surface of the semiconductor film 31. The charge storage film 34 surrounds a side surface of the tunnel insulating film 33. The cover insulating film 36 surrounds a side surface of the charge storage film 34. The insulator layer 43 surrounds a side surface of the block insulating film 36.

As illustrated in FIG. 7 and FIG. 8, a thickness R34a in the radial direction of the charge storage film 34 in the XY cross section including the interconnect layer 23 is greater than a thickness R34b in the radial direction of the charge storage film 34 in the XY cross section including the insulator layer 43. A thickness R35 in the radial direction of the block insulating film 35 in the XY cross section including the interconnect layer 23 is less than a thickness R36 in the radial direction of the cover insulating film 36 in the XY cross section including the insulator layer 43. A total thickness (R34a + R35) in the radial direction of the charge storge film 34 and block insulating film 35 in the XY cross section including the interconnect layer 23 is substantially equal or less than a total thickness (R34b + R36) in the radial direction of the charge storge film 34 and cover insulating film 36 in the XY cross section including the insulator layer 43 (R34a + R35 ≤ R34b + R36).

Although not illustrated, also in the XY cross sections including the interconnect layers 22 and 24, like the XY cross section including the interconnect layer 23, the memory pillar MP has the configuration as illustrated in FIG. 6 and FIG. 7. Also in the XY cross sections including the insulator layers 41, 42, 44 and 45, like the XY cross section including the interconnect layer 43, the memory pillar MP has the configuration as illustrated in FIG. 6 and FIG. 8.

The radii of the memory pillar MP in each of the XY cross sections including the interconnect layers 22 to 24 and the insulator layers 41 to 45, respectively, may not necessarily be equal. For example, the memory pillar MP may have a taper shape having a radius decreasing from above to below. In addition, the cross-sectional shape of the memory pillar MP in the XY cross section including any one of the interconnect layers 22 to 24 and insulator layers 41 to 45 may be an elliptic shape.

By the above configuration, each memory pillar MP can function as one NAND string NS.

### 1.4.3. Hookup Area

### Planar Layout

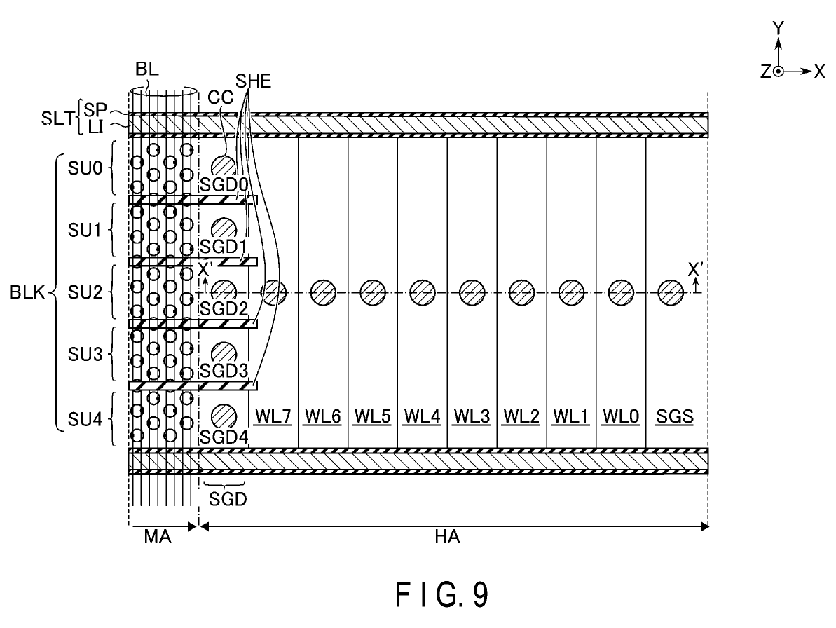

FIG. 9 is a plan view illustrating an example of a planar layout in a hookup area of the memory cell array included in the semiconductor memory device according to the embodiment. FIG. 9 illustrates the hookup area HA and a part of the memory area MA near the hookup area HA. Note that in FIG. 9, for the purpose of simple description, some insulator layers are omitted. As illustrated in FIG. 9, in the hookup area HA, the memory cell array 10 includes a plurality of contacts CC.

As illustrated in FIG. 9, in the hookup area HA, each of the interconnect layers 22, 23 and 24 includes a terrace portion that does not overlap, in the Z direction, the interconnect layers 23 and 24 provided in upper layers above this interconnect layer. The shape of the terrace portion in the hookup area HA is similar to a step, a terrace, a rimstone, or the like. The terrace portions of the interconnect layers 22, 23 and 24 are arranged, for example, in the X direction. The contacts CC are coupled to the terrace portions of the interconnect layers 22 and 23.

As illustrated in FIG. 9, the select gate line SGD includes select gate lines SGD0 to SGD4 that are formed of portions divided into five in the Y direction by four members SHE in the terrace portion of the corresponding interconnect layer 24. The respective portions of the select gate lines SGD0 to SGD4 divided in the Y direction by the four members SHE are insulated from each other. The contacts CD are coupled to the terrace portions of the select gate lines SGD0 to SGD4.

In the hookup area HA, the contacts CC are provided to correspond to the select gate lines SGS and SGD and word lines WL0 to WL7. As illustrated in FIG. 9, the contacts CC corresponding to the select gate lines SGD are arranged in the Y direction. The contacts CC corresponding to the select gate line SGS and word lines WL0 to WL7 are arranged, for example, in the X direction.

### Cross-Sectional Configuration

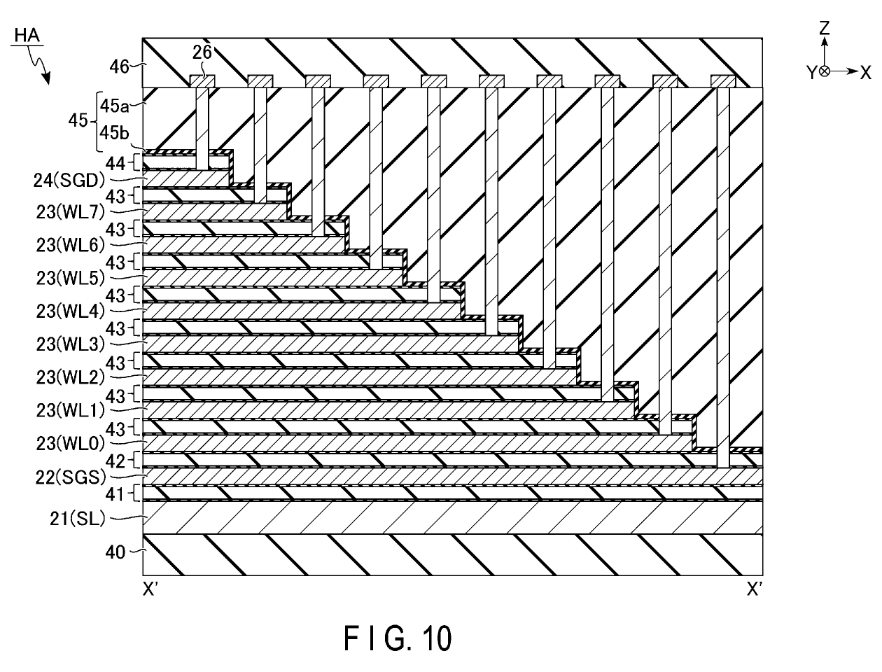

FIG. 10 is a cross-sectional view taken along line X'-X' in FIG. 9, in the hookup area of the memory cell array included in the semiconductor memory device according to the embodiment. FIG. 10 illustrates an XZ cross section of the hookup area HA and contacts CC. As illustrated in FIG. 10, in the hookup area HA, the memory cell array 10 further includes a plurality of interconnect layers 26.

As illustrated in FIG. 10, in the hookup area HA, such a staircase structure is provided that the terrace portions of the interconnect layers 22 to 24 successively descend in a direction away from the memory area MA. The insulator layers 42 to 44 stacked in contact with the upper surfaces of the interconnect layers 22 to 24 are provided in such a manner to cover the terrace portions of the corresponding interconnect layers 22 to 24. Specifically, the staircase structure is configured such that each of a pair of the interconnect layer 22 and insulator layer 42, pairs of the interconnect layers 23 and insulator layer 43, and a pair of the interconnect layer 24 and insulator layer 44 forms one step of the staircase.

The insulator layer 45 is provided in such a manner as to fill the staircase structure. Specifically, the coat film 45b is provided in such a manner as to cover upper surfaces (tread surfaces) and side surfaces (riser surfaces) of the staircase structure. In other words, the coat film 45b covers the terrace portion of each of the interconnect layers 22 to 24, and an X-directional side surface portion at an end portion of each of the interconnect layers 22 to 24. The insulator 45a is buried above the coat film 45b.

The contacts CC extend in the Z direction. An upper surface of each contact CC is in contact with the interconnect layer 26. A lower surface of each contact CC is in contact with one of the interconnect layers 22 to 24, to which this contact CC corresponds. Each contact CC penetrates (passes through) the insulator layer 45 provided at the position where this contact CC is disposed in plan view, and one of the insulator layers 42 to 44 provided in a manner to cover the terrace portion of one of the interconnect layers 22 to 24, to which this contact corresponds.

The interconnect layers 26 are provided in contact with the contacts CC, respectively. Each contact CC is electrically coupled to the row decoder module 16 via the corresponding interconnect layer 26.

### 2. MANUFACTURING METHOD

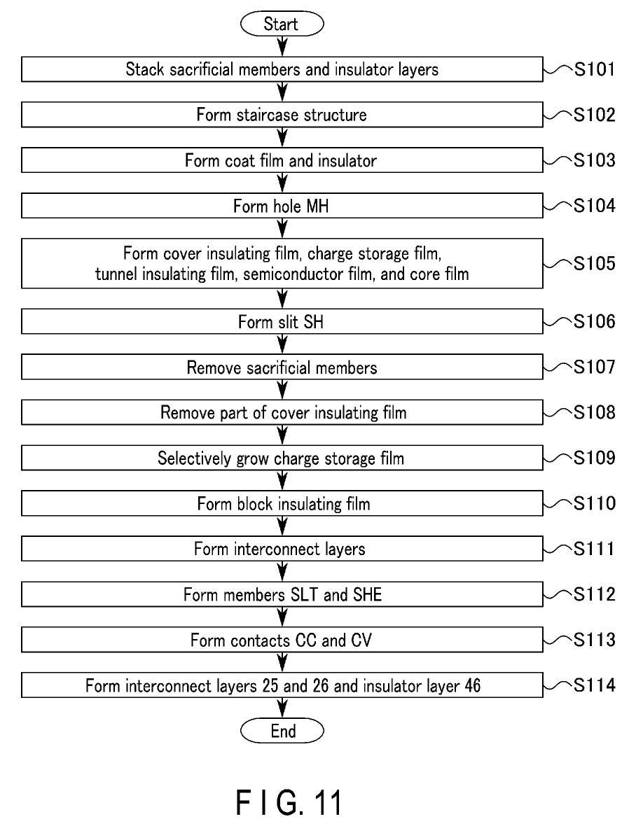

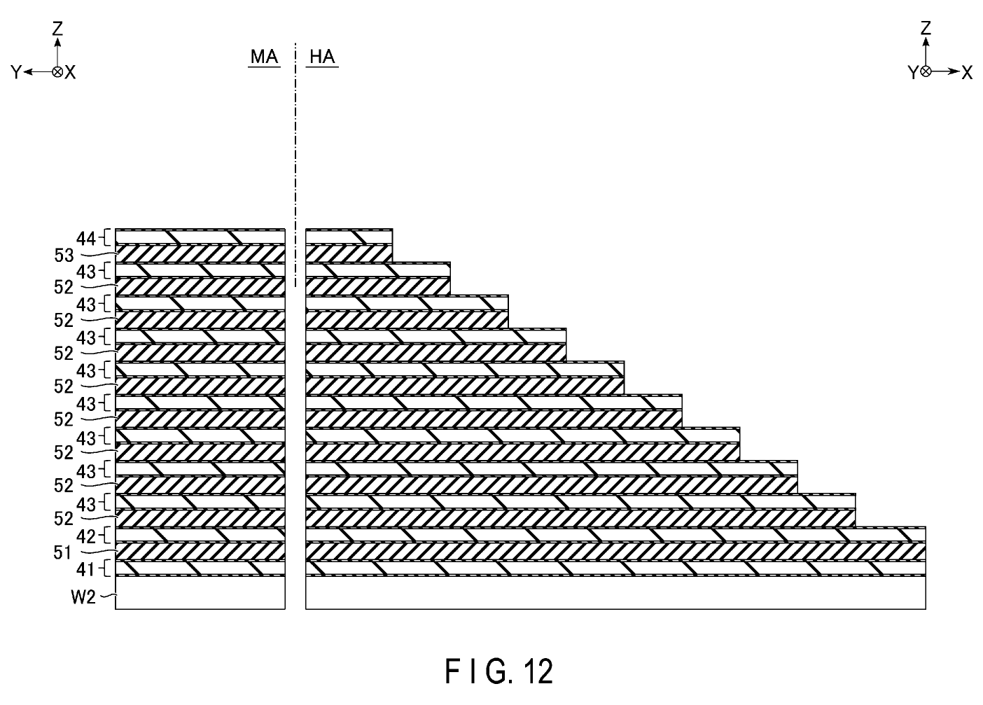

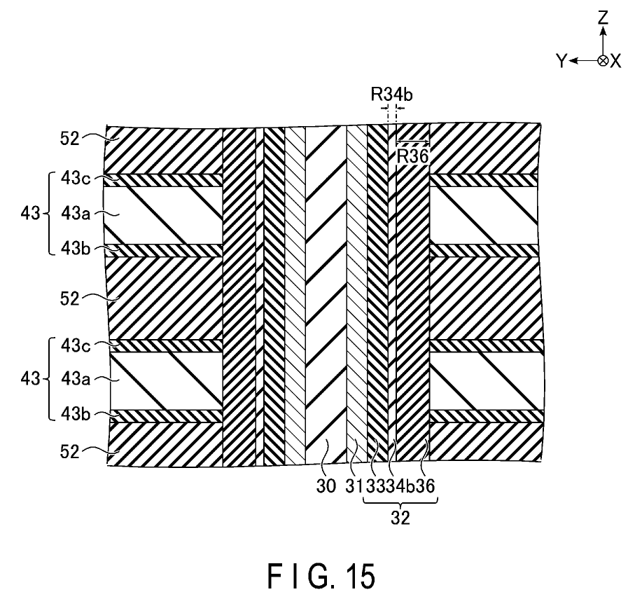

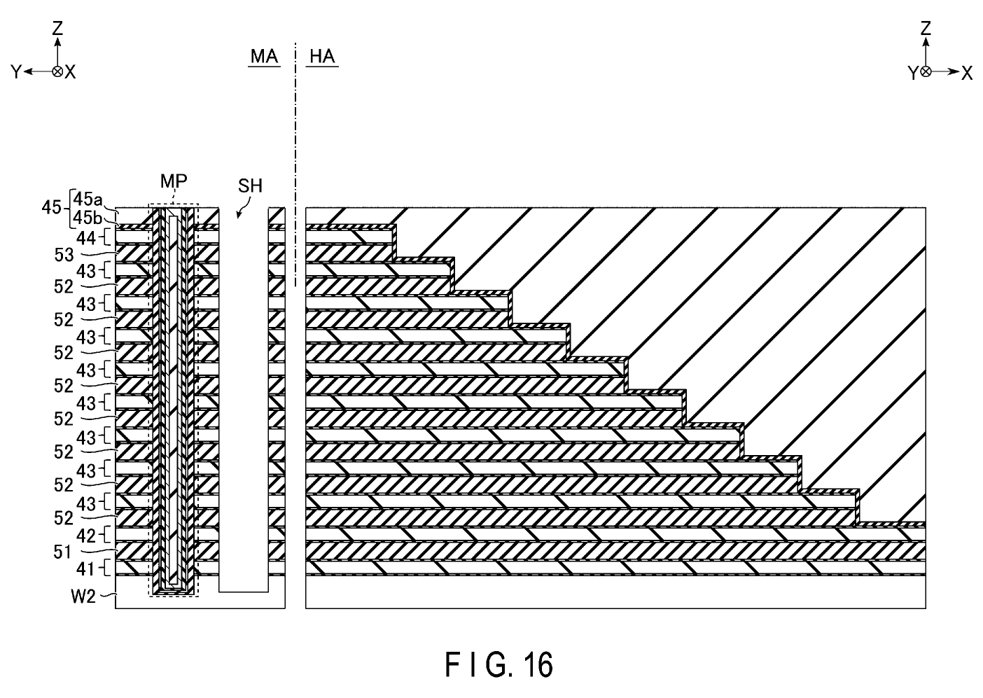

FIG. 11 is a flowchart illustrating an example of manufacturing steps of the memory cell array included in the semiconductor memory device according to the embodiment. Each of FIG. 12 to FIG. 24 illustrates an example of a cross-sectional configuration during the manufacture of the semiconductor memory device according to the embodiment. Each of FIG. 12 to FIG. 14, FIGS. 16 and 17, and FIG. 22 to FIG. 24 illustrates an area corresponding to FIG. 10, and a part of the memory area MA illustrated in FIG. 5. Each of FIG. 15 and FIGS. 18 to 21 illustrates an area corresponding to FIG. 6.

As illustrated in FIG. 11, in the manufacturing steps of the memory cell array 10, processes of S101 to S114 are successively executed. Hereinafter, referring to FIG. 12 to FIG. 24 as appropriate, an example of the manufacturing steps of the memory cell array 10 is described.

In the present embodiment, a case is described in which, as a forming method of the interconnect layers 22, 23 and 24 corresponding to the select gate lines SGS and SGD and word lines WL0 to WL7, for example, use is made of a method (hereinafter referred to as "replace") in which after structures corresponding to the interconnect layers 22, 23 and 24 are formed of sacrificial members, the sacrificial members are replaced with conductive materials, thereby forming the respective interconnect layers.

To start with, the processes of S101 and S102 are successively executed, a stacked structure is formed, and a staircase structure is formed in the hookup area HA. Specifically, an insulator layer 41, a sacrificial member 51, and an insulator layer 42 are stacked in the named order on a second semiconductor substrate W2. On the insulator layer 42, eight sacrificial members 52 and eight insulator layers 43 are alternately stacked one by one. On the uppermost insulator layer 43, a sacrificial member 53 and an insulator layer 44 are stacked in the named order (S101). Note that each of the insulator layers 41, 42, 43 and 44 is formed such that a second insulating film, a first insulating film and a third insulating film are stacked in the named order. The sacrificial members 51, 52 and 53 include, for example, SiN. Then, as illustrated in FIG. 12, a staircase structure is formed in the hookup area HA (S102). To begin with, by photolithography or the like, a mask with an opening in a portion corresponding a lowest step of the staircase structure is formed. Then, by anisotropic etching using the mask, the sacrificial member 52 and insulator layer 43 for one step are removed. Next, in the mask, a portion corresponding to a second lowest step of the staircase structure is removed. Then, by anisotropic etching using the mask, the sacrificial member 52 and insulator layer 43 for one step are removed. In this manner, by repeating the reduction of the mask area and the anisotropic etching, the sacrificial members 52 and insulator layers 43 are shaped in a staircase fashion. Finally, in the mask, a portion corresponding to a second highest step of the staircase structure is removed, and by anisotropic etching using the mask, the sacrificial member 53 and insulator layer 44 are removed. In this manner, the sacrificial member 53 and insulator layer 44 are shaped in a staircase fashion.

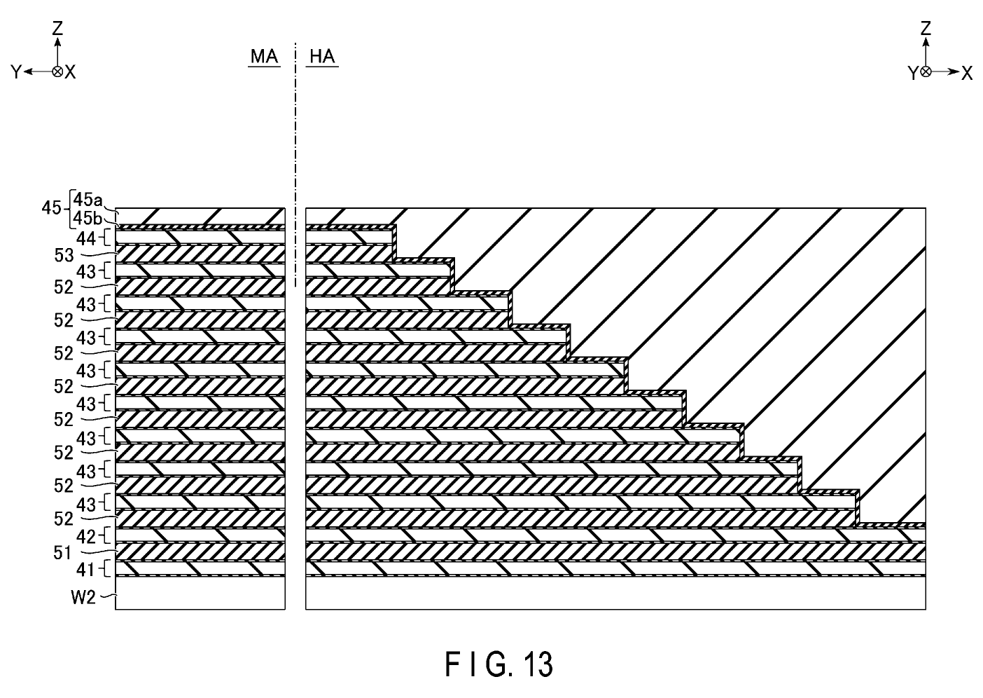

Next, the process of S103 is executed, and a coat film 45b and an insulator 45a are formed. Specifically, as illustrated in FIG. 13, at first, the coat film 45b is formed on a surface of the stacked structure by using CVD (Chemical Vapor Deposition). At this time, the coat film 45b is formed on side surfaces (riser surfaces) as well as upper surfaces (tread surfaces) of the staircase structure. Thereafter, on the coat film 45b, the insulator 45a is formed in such a manner as to fill the staircase structure. For example, an upper surface of the insulator 45a is planarized by CMP (Chemical Mechanical Polishing). By the above, the insulator layer 45 is formed.

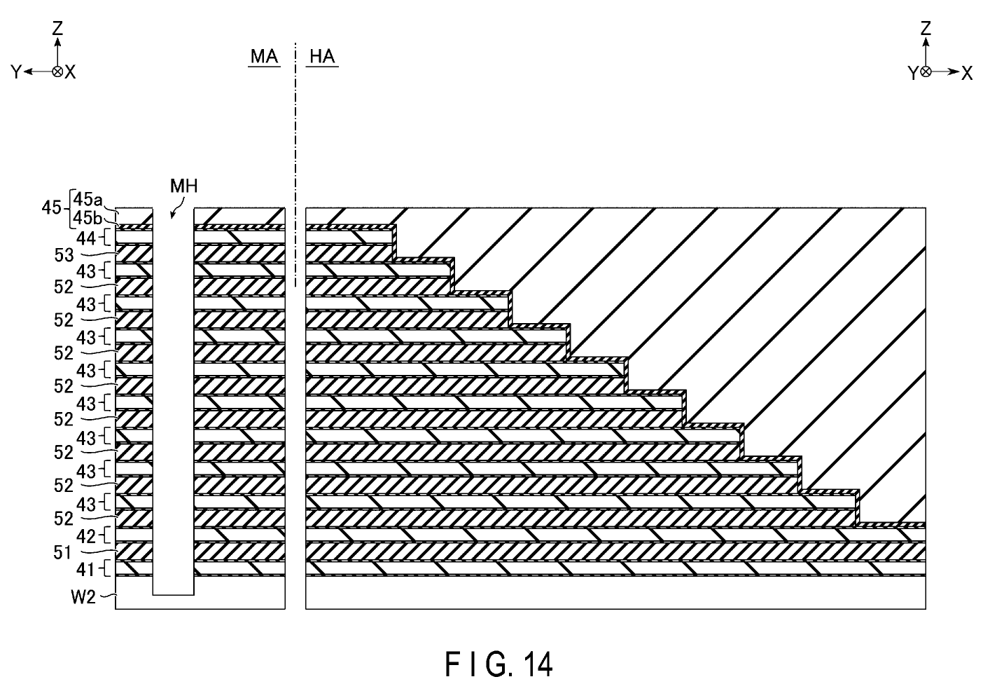

Next, the process of S104 is executed, and a hole MH corresponding to the memory pillar MP is formed. Specifically, at first, by photolithography or the like, a mask with openings in areas corresponding to the memory pillars MP is formed. Then, as illustrated in FIG. 14, by anisotropic etching using the mask, a plurality of holes MH corresponding to the memory pillars MP are formed. Each hole MH penetrates the insulator layers 41 to 45 and sacrificial members 51 to 53. A bottom portion of each hole MH is located in the second semiconductor substrate W2, and a part of the second semiconductor substrate W2 is exposed.

Next, the process of S105 is executed, and a core film 30, a semiconductor film 31, and a part of a structure corresponding to a stacked film 32 of the memory pillar MP are formed. Specifically, at first, as illustrated in FIG. 15, a cover insulating film 36, a charge storage film 34b, a tunnel insulating film 33, a semiconductor film 31 and a core film 30 are successively formed from the outside of the hole MH by ALD (Atomic Layer Deposition) or CVD. At this time, a thickness of the cover insulating film 36 is a thickness R36 in the radial direction of the cover insulating film 36 in the XY cross section including the insulator layer 43. A thickness of the charge storage film 34b is a thickness R34b in the radial direction of the charge storage film 34 in the XY cross section including the insulator layer 43. The charge storage film 34b includes, for example, SiN.

Next, the process of S106 is executed, and a slit SH corresponding to the member SLT is formed. Specifically, at first, by photolithography or the like, a mask with an opening in an area corresponding to each member SLT is formed. Then, by anisotropic etching using the mask, as illustrated in FIG. 16, a plurality of slits SH corresponding to the members SLT are formed. Each slit SH divides the insulator layers 41 to 45 and sacrificial members 51 to 53 in the Y direction. At a bottom portion of each slit SH, a part of the second semiconductor substrate W2 is exposed.

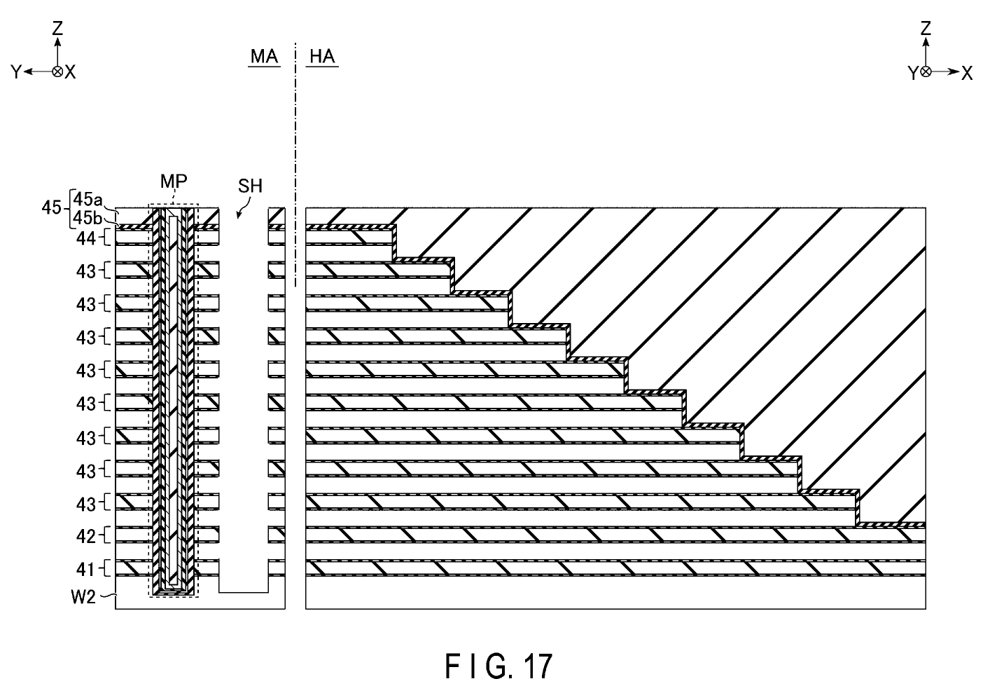

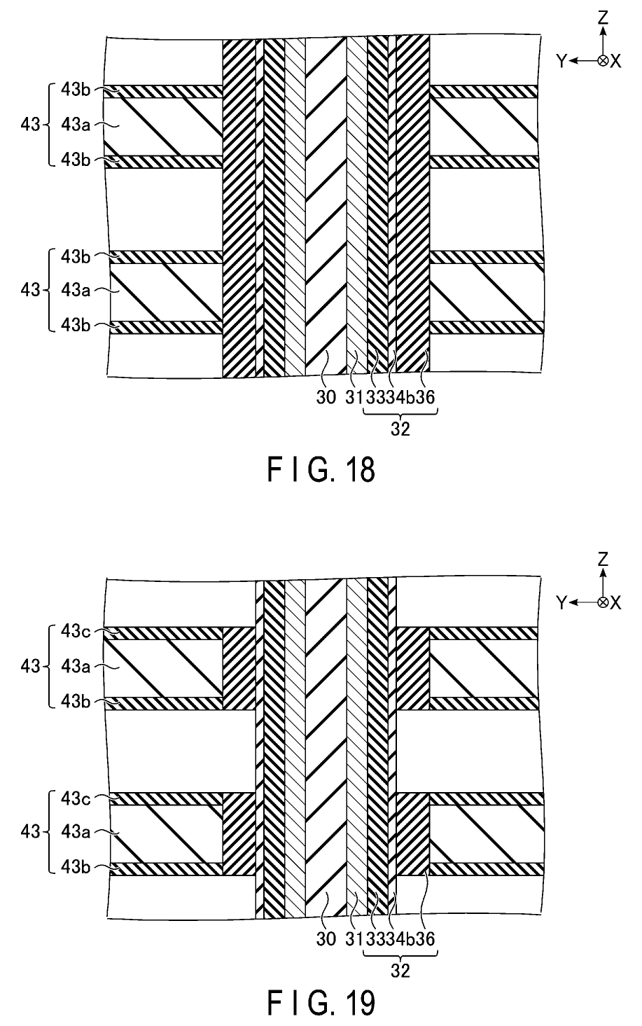

Next, the process of S107 is executed, and the sacrificial members 51, 52 and 53 are removed. Specifically, as illustrated in FIG. 17 and FIG. 18, the sacrificial members 51, 52 and 53 are selectively etched and removed by using a solution or gas including phosphoric acid. This etching process is performed via the slit SH. A three-dimensional structure of the memory cell array 10, from which the sacrificial members 51, 52 and 53 are removed, is supported by a plurality of memory pillars MP and a plurality of support pillars (not illustrated) that are arranged as appropriate. At parts where the sacrificial members 51, 52 and 53 are removed, the cover insulating film 36 is exposed.

Next, the process of S108 is executed, and the cover insulating film 36 at the exposed part is removed. Specifically, as illustrated in FIG. 19, by using a solution or gas including hydrofluoric acid (for example, buffered hydrogen fluoride (BHF)), the cover insulating film 36 exposed at parts, from which the sacrificial members 51, 52 and 53 are removed, is selectively subjected to anisotropic etching, and removed. This etching process is performed via the slit SH. At the parts from which the cover insulating film 36 is removed, the charge storage film 34b is exposed.

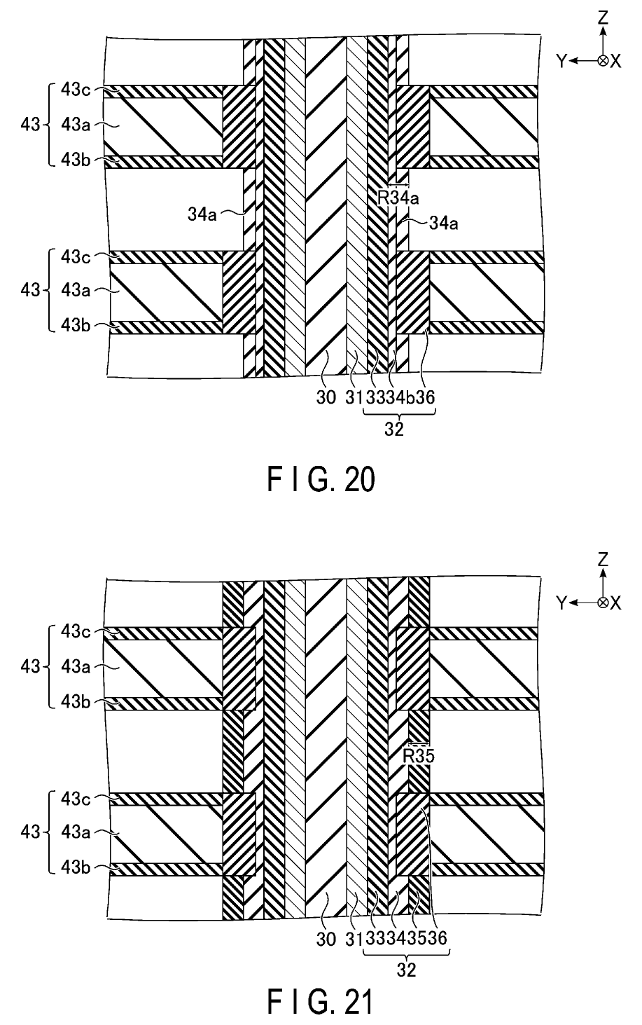

Next, the process of S109 is executed, and the charge storage film 34 at the exposed part is selectively grown. Specifically, as illustrated in FIG. 20, a charge storage film 34a is grown on the surface of the charge storage film 34b by using the charge storage film 34b at the exposed part as a seed. A total thickness of the charge storage film 34b and charge storage film 34a becomes a thickness R34a in the radial direction of the charge storage film 34 in the XY cross section including the interconnect layer 23. The charge storage film 34a includes, for example, SiN. Hereinafter, a description is given by regarding the charge storage films 34a and 34b as a single charge storage film 34.

Next, the process of S110 is executed, and a block insulating film 35 is formed. Specifically, as illustrated in FIG. 21, the block insulating film 35 is formed by ALD or CVD on surfaces of the exposed parts of the charge storage film 34. A thickness of the block insulating film 35 is a thickness R35 in the radial direction of the block insulating film 35 in the XY cross section including the interconnect layer 23.

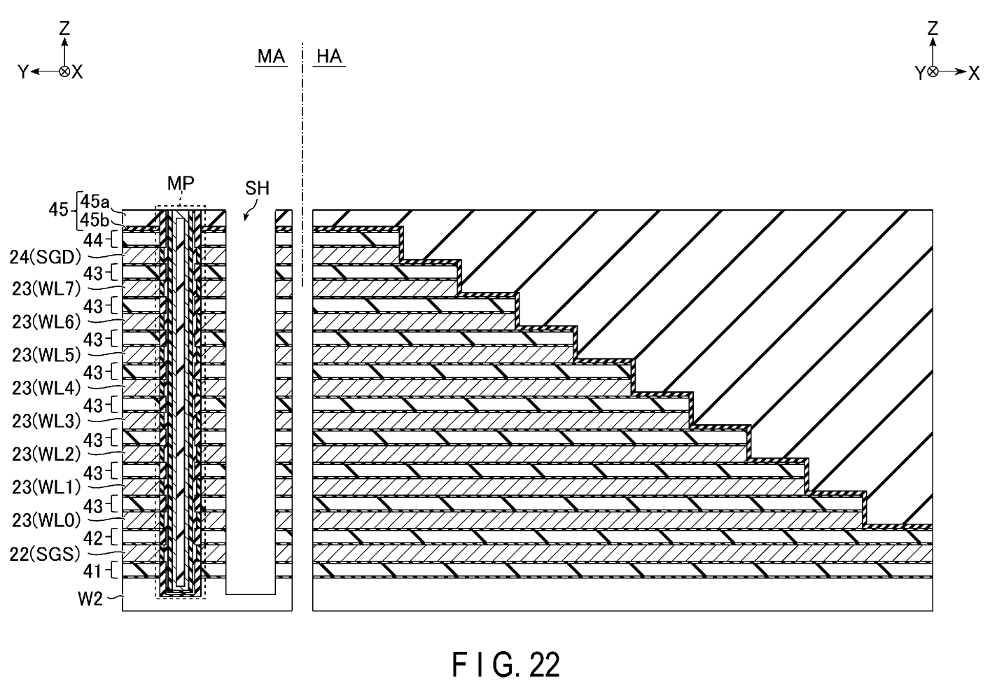

Next, the process of S111 is executed, and interconnect layers 22, 23 and 24 are formed. Specifically, as illustrated in FIG. 22, a conductive material (for example, tungsten) is buried in the spaces, from which the sacrificial members 51, 52 and 53 are removed, via the slit SH by CVD or the like. Note that in a case where the interconnect layers 22, 23 and 24 include barrier films, for example, films of AlO or the like are formed as the barrier films after the process of S110, and then the conductive material is buried. Thereafter, the conductive material formed in the slit SH is removed by an etch-back process, and the conductive materials of the interconnect layers, which neighbor each other in the Z direction, are separated from each other. Thereby, the interconnect layer 22 functioning as the select gate line SGS, the interconnect layers 23 functioning as the word lines WL0 to WL7, and the interconnect layer 24 functioning as the select gate line SGD, are formed.

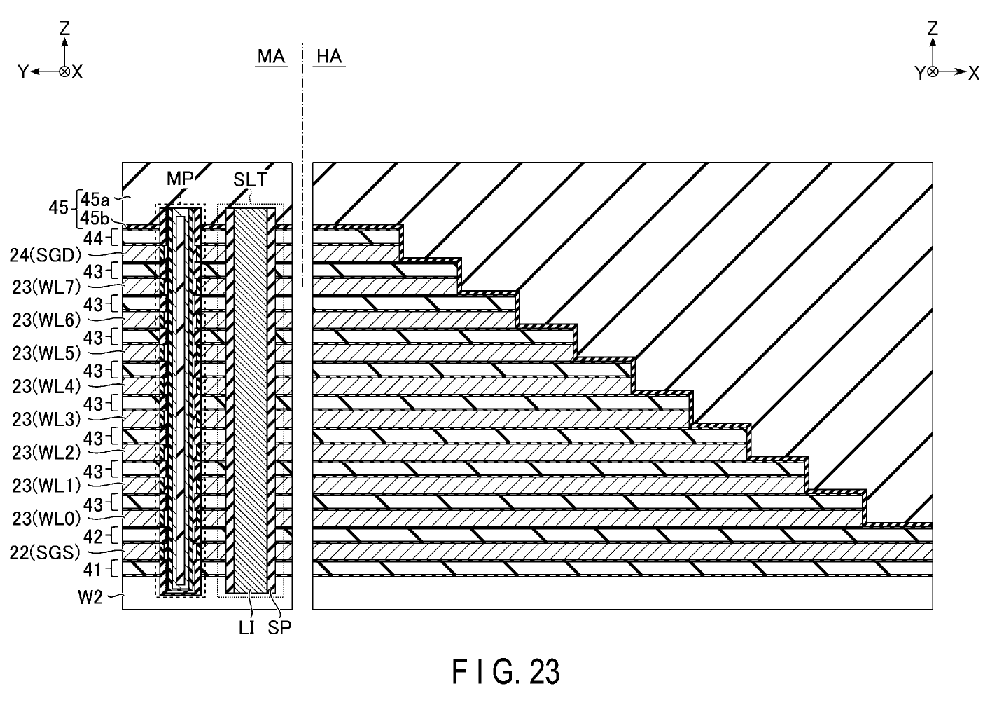

Next, the process of S112 is executed, and, as illustrated in FIG. 23, a member SLT is formed in each slit SH. In addition, although not illustrated, a member SHE is formed in the select gate line SGD extending from the memory area MA to a part of the hookup area HA. Specifically, a spacer SP is first formed in a manner to cover a side surface and a bottom surface of the slit SH. Then, a part of the spacer SP provided in a bottom portion of the slit SH is removed, and a part of the second semiconductor substrate W2 is exposed in the bottom portion of the slit SH. Then, a conductor (contact LI) is formed in the slit SH, and a conductor formed outside the slit SH is removed by, for example, CMP. Thereafter, in areas corresponding to members SHE between members SLT that neighbor each other in the Y direction, a plurality of grooves are formed in parallel to the members SLT. Then, an insulator (for example, SiO) is buried in each groove, and thereby the member SHE that divides the interconnect layer 24 in the Y direction is formed. Thereafter, as illustrated in FIG. 23, an insulator 45a is further stacked.

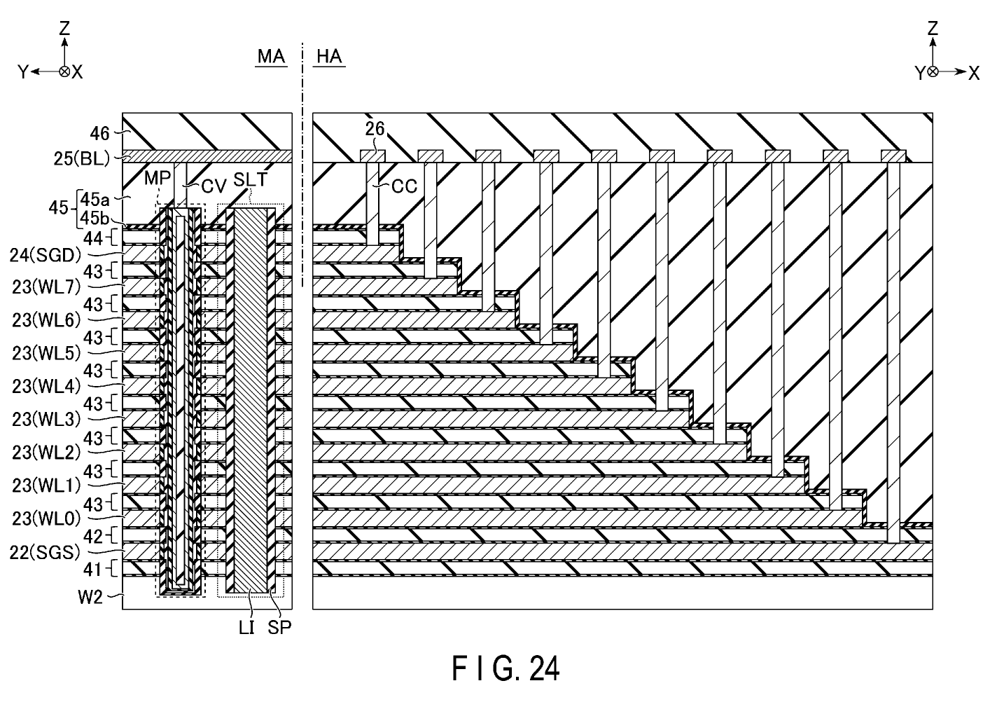

Next, the processes of S113 and S114 are executed, and, as illustrated in FIG. 24, contacts CC and CV, interconnect layers 25 and 26, and an insulator layer 46 are formed. Specifically, at first, by photolithography or the like, a mask with openings in areas corresponding to the contacts CC and CV is formed. Then, by anisotropic etching using the mask, holes corresponding to the contacts CC and CV are formed. Thereafter, a conductor is buried in the holes, and the contacts CC and CV are formed (S113). Next, an interconnect layer 25 functioning as the bit line BL is formed to extend in the Y direction and to be in contact with an upper surface of the contact CV. Interconnect layers 26 are formed to extend in the Y direction and to be in contact with upper surfaces of the contacts CC. Thereafter, an insulator layer 46 is formed above the interconnect layers 25 and 26 (S114). After the end of the process of S114, for example, the second semiconductor substrate W2 including the memory cell array 10 and the first semiconductor substrate are bonded. After the bonding, for example, the second semiconductor substrate W2 and a part of the stacked film 32 are removed, and an interconnect layer 21 and an insulator layer 40 are formed. At this time, the interconnect layer 21 and the semiconductor film 31 of the memory pillar MP are electrically coupled.

By the above-described manufacturing steps, the structure of the memory cell array 10 is formed. Note that the above-described manufacturing steps are merely an example, and are not limited to this. For example, other processes may be inserted between the manufacturing steps, or some steps may be omitted or integrated. Furthermore, the manufacturing steps can be interchanged if possible.

### 3. ADVANTAGEOUS EFFECTS ACCORDING TO EMBODIMENT

According to the embodiment, the yield of semiconductor memory devices can be improved. This advantageous effect is described below in detail.

In the manufacturing steps of the memory cell array 10 included in the semiconductor memory device 3 according to the embodiment, at a time of removing the cover insulating film 36 in the process of S108 illustrated in FIG. 11, etching using a solution or gas including hydrofluoric acid is performed. At this time, the solution or gas including hydrofluoric acid flows, via the slit SH and the parts from which the sacrificial members 51, 52 and 53 are removed, not only into the vicinity of the memory pillar MP but also into the parts in which the staircase structure is formed in the hookup area HA. Thus, there is a possibility that the solution or gas including hydrofluoric acid unintendedly removes parts of the insulator layers 42, 43, 44 and 45, for example, at the side surface (riser surface) portions of the staircase structure. If the solution or gas including hydrofluoric acid removes parts of the insulator layers 42, 43, 44 and 45 at the side surface portions of the staircase structure, hammerhead-shaped spaces, for example, are formed in the side surface portions of the staircase structure. Thereafter, in the process of S111, the conductive material (for example, tungsten) is poured, and fills the spaces. As a result, there is a possibility that the interconnect layer, which constitutes the staircase structure, is coupled to the upper and lower interconnect layers via the hammerhead-shaped portions, and short-circuit between the interconnect layers occurs.

According to the present embodiment, the coat film 45b is formed on the side surfaces of the staircase structure in the hookup area HA of the memory cell array 10. The coat film 45b includes, for example, SiOC, and has a lower etching rate by hydrofluoric acid than the cover insulating film 36. Accordingly, at the time of etching using the solution or gas including hydrofluoric acid in the process of S108 illustrated in FIG. 11, it is possible to suppress removal of the insulator layers 42, 43, 44 and 45 in the side surface portions of the staircase structure. As a result, spaces are not formed easily in the side surface portions of the staircase structure, the occurrence of short-circuit between the interconnect layers via the conductive material buried in the spaces can be suppressed, and the yield of semiconductor memory devices 3 can be improved.

Furthermore, according to the present embodiment, the thickness R34a in the radial direction of the charge storage film 34 in the XY cross section including the interconnect layer 22, 23 or 24 is greater than the thickness R34b in the radial direction of the charge storage film 34 in the XY cross section including the insulator layer 41, 42, 43, 44 or 45. In other words, the continuity of the charge storage film 34 in the Z direction is disrupted in a pseudo-manner by the cover insulating film 36 in the cross section including the insulator layer 41, 42, 43, 44 and 45. Thereby, at a time of the operation of the memory cell transistor MT, it is possible to suppress movement of the charge trapped in one of the charge storage film 34 into the other charge storage film 34 corresponding to another neighboring memory cell transistor MT in the Z direction. In other words, an unintended change of data memorized in the memory cell transistor MT due to the movement of charge can be suppressed, and the reliability of the semiconductor storage device 3 can be improved.

### 4. MODIFICATIONS

The semiconductor memory device 3 according to the embodiment can be variously modified. Hereinafter, a first modification and a second modification of the embodiment are described with respect to different points from the embodiment.

### 4.1. First Modification

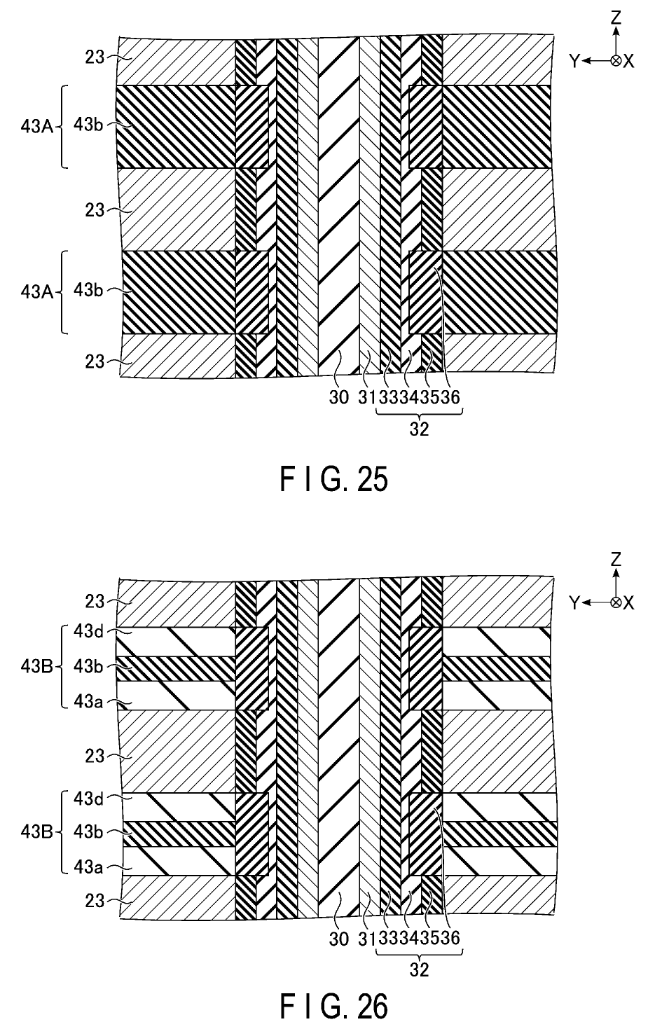

FIG. 25 is a cross-sectional view illustrating an example of a cross-sectional configuration in a memory area of a memory cell array included in a semiconductor memory device according to a first modification of the embodiment. The area illustrated in FIG. 25 is an area corresponding to FIG. 6 in the embodiment.

As illustrated in FIG. 25, the memory cell array 10 included in the semiconductor memory device 3 according to the first modification of the embodiment includes an insulator layer 43A in place of the insulator layer 43. The insulator layer 43A does not include the first insulating film 43a or the third insulating film 43c, and includes the second insulating film 43b.

In addition, although not illustrated, the configuration of the insulator layers 41, 42 and 44 is also replaced with the configuration that does not include the first insulating film or the third insulating film, and includes the second insulating film.

### 4.2. Second Modification

FIG. 26 is a cross-sectional view illustrating an example of a cross-sectional configuration in a memory area of a memory cell array included in a semiconductor memory device according to a second modification of the embodiment. The area illustrated in FIG. 26 is an area corresponding to FIG. 6 in the embodiment.

As illustrated in FIG. 26, the memory cell array 10 included in the semiconductor memory device 3 according to the second modification of the embodiment includes an insulator layer 43B in place of the insulator layer 43. The insulator layer 43B includes a first insulating film 43a, a second insulating film 43b and a fourth insulating film 43d. The second insulating film 43b is provided in a central portion of the insulating layer 43B. The first insulating film 43a is provided in such a manner as to cover a lower surface of the second insulating film 43b. The fourth insulating film 43d is provided in such a manner as to cover an upper surface of the second insulating film 43b. Specifically, the first insulating film 43a and fourth insulating film 43d are provided in a manner to sandwich the corresponding second insulating film 43b in the Z direction. The fourth insulating film 43d includes, for example, SiO.

In addition, although not illustrated, the configuration of the insulator layers 41, 42 and 44 is also replaced with the configuration in which the second insulating film is provided in the central portion of the insulating layer, and the first insulating film and the fourth insulating film are provided in a manner to cover the lower surface ad upper surface of the second insulating film and to sandwich the second insulating film in the Z direction. The fourth insulating film includes, for example, SiO.

### 5. OTHERS

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of interconnect layers and a plurality of first insulating films provided to extend over a first area and a second area that are arranged, as viewed in a first direction, in a second direction crossing the first direction, and alternately stacked in the first direction;
a memory pillar extending and passing through the interconnect layers and the first insulating films in the first direction in the second area, and in which portions passing through the interconnect layers function as memory cells, wherein the memory pillar includes a semiconductor extending in the first direction, a second insulating film provided between the semiconductor, and the interconnect layers and the first insulating films, a charge storage film provided between the second insulating film, and the interconnect layers and the first insulating films, a plurality of third insulating films provided between the charge storage film and the interconnect layers, and a plurality of fourth insulating films including a first film type and provided between the charge storage film and the first insulating films; and
a fifth insulating film, including a second film type having a lower etching rate to hydrofluoric acid than the first film type, provided in the first area in such a manner as to cover side surface portions in the second direction at end portions of the interconnect layers.

2. The semiconductor memory device of claim 1, wherein the second film type includes carbon.

3. The semiconductor memory device of claim 2, wherein the second film type includes silicon oxycarbide.

4. The semiconductor memory device of claim 3, wherein the first film type includes silicon oxide, hafnium oxide, or zirconium oxide.

5. The semiconductor memory device of claim 1, wherein the interconnect layers include in the first area a staircase structure in which terrace portions are arranged in the second direction, the terrace portions being provided not overlapping respective upper layers of the interconnect layers in the first direction.

6. The semiconductor memory device of claim 5, wherein
the fifth insulating film further covers the terrace portions of the interconnect layers.

7. The semiconductor memory device of claim 6, wherein a film thickness of the fifth insulating film is less than a film thickness of each of the first insulating films.

8. The semiconductor memory device of claim 1, wherein the charge storage film includes:
a plurality of first portions provided between the second insulating film and the third insulating films, a thickness in the second direction of each of the first portions having a first thickness; and
a plurality of second portions provided between the second insulating film and the fourth insulating films, a thickness in the second direction of each of the second portions having a second thickness that is less than the first thickness.

9. The semiconductor memory device of claim 8, wherein each of the fourth insulating films includes a portion that is sandwiched between the first portions of the charge storage film in the first direction, the first portions being spaced apart in the first direction.

10. The semiconductor memory device of claim 8, wherein
each of the third insulating films has a third thickness in the second direction,
each of the fourth insulating films has a fourth thickness in the second direction, and
a sum of the second thickness and the fourth thickness is substantially equal to, or greater than, a sum of the first thickness and the third thickness.

11. The semiconductor memory device of claim 1, wherein the first insulating film includes the second film type.

12. The semiconductor memory device of claim 11, wherein each of the first insulating films includes:
a third portion including a third film type different from the second film type, and extending in the second direction; and
a plurality of fourth portions including the second film type, extending in the second direction, and being provided in such a manner as to sandwich the third portion in the first direction.

13. The semiconductor memory device of claim 11, wherein each of the first insulating films includes:
a third portion including the second film type, and extending in the second direction; and
a plurality of fourth portions including a third film type different from the second film type, extending in the second direction, and being provided in such a manner as to sandwich the third portion in the first direction.

14. The semiconductor memory device of claim 5, further comprising a contact extending in the first direction in the first area, and being coupled to one of the terrace portions of the interconnect layers.

15. A semiconductor memory device comprising:
a plurality of interconnect layers and a plurality of first insulating films, the interconnect layers and the first insulating films being provided to extend over a first area and a second area that are arranged, as viewed in a first direction, in a second direction crossing the first direction, and the interconnect layers and the first insulating films being alternately stacked in the first direction;
a fifth insulating film provided in the first area in such a manner as to cover side surface portions in the second direction at end portions of the interconnect layers, the fifth insulating film including silicon oxycarbide; and
a memory pillar extending and passing through the interconnect layers and the first insulating films in the first direction in the second area, and in which portions passing through the interconnect layers function as memory cells.

16. The semiconductor memory device of claim 15, wherein the interconnect layers include in the first area a staircase structure in which terrace portions are arranged in the second direction, the terrace portions being provided not overlapping respective upper layers of the interconnect layers in the first direction.

17. The semiconductor memory device of claim 16, wherein
the fifth insulating film further covers the terrace portions of the interconnect layers.

18. The semiconductor memory device of claim 17, wherein a film thickness of the fifth insulating film is less than a film thickness of each of the first insulating films.

19. The semiconductor memory device of claim 15, wherein the memory pillar includes:
a semiconductor extending in the first direction;
a second insulating film provided between the semiconductor, and the interconnect layers and the first insulating films;
a charge storage film provided between the second insulating film, and the interconnect layers and the first insulating films;
a plurality of third insulating films provided between the charge storage film and the interconnect layers; and
a plurality of fourth insulating films provided between the charge storage film and the first insulating films.

20. The semiconductor memory device of claim 16, further comprising a plurality of contacts extending in the first direction in the first area, and being coupled to the terrace portions of the interconnect layers, respectively.
